(19) United States
(12) Patent Application Publication
(10) Pub. No.: US 2026/0190990 A1
(43) Pub. Date: Jul. 2, 2026

(54) HEAT DISSIPATION STRUCTURE IN ADVANCED CHIP PACKAGE

(71) Applicant: Intel Corporation, Santa Clara, CA (US)

(72) Inventors: Yen Kun LAI, Hsinchu City (TW); Po Yao LIN, New Taipei City (TW); Kai Chiang WU, Hsinchu City (TW); Han-Wen LIN, Zhubei City (TW); Yanling HUANG, Taoyuan City (TW)

(21) Appl. No.: 19/002,800

(22) Filed: Dec. 27, 2024

(51) Int. Cl. H01L 23/00; H01L 23/373

(52) U.S. Cl. CPC H10W 40/251; H10W 72/01323; H10W 72/07338; H10W 72/07352; H10W 72/321; H10W 72/324; H10W 72/325; H10W 72/342; H10W 72/352; H10W 72/354; H10W 72/387

(57) ABSTRACT

A device including: a substrate; a chip module coupled to the substrate; a first thermal material disposed on the chip module; a second thermal material disposed on the chip module; a lid structure disposed over the chip module and coupled to the substrate with adhesive along a perimeter of the lid structure, wherein a central portion of the lid structure is in thermal contact with the first thermal material and the second thermal material; and a support structure arranged around the chip module and covered by the lid structure, the support structure extending vertically from the substrate to the lid structure.

### BACKGROUND

Due to the increasing processing and/or throughput demands of high-performance chips, the power level and heat generation from die(s)/chip module(s) are increasing. Semiconductor industries are developing thermally enhanced chip packaging to provide adequate heat dissipation from the die backside to the integrated heat spreader or lid. High thermal conductivity and low bond line thickness (BLT) of the thermal interface material (TIM) has been considered to improve heat dissipation and lower junction temperature.

Therefore, there exists a need to provide improved heat dissipation structures in advanced chip packaging and processes for making the same.

### BRIEF DESCRIPTION OF THE DRAWINGS

The accompanying drawings serve to provide an understanding of non-limiting aspects. Further non-limiting aspects and many of the intended advantages will become apparent directly from the following detailed description. The elements and structures shown in the drawings are not necessarily shown to scale relative to each other. Like reference numerals refer to like or corresponding elements and structures. Non-limiting aspects will be better understood by one of ordinary skill in the art from the following detailed description and in conjunction with the drawings, in which:

FIGS. 1A and 1B are schematic diagrams showing a top view (without lid) and a cross-sectional view (with lid) of a current chip package;

FIGS. 2A and 2B are schematic diagrams showing a top view (without lid) and a cross-sectional view (with lid) of another current chip package;

FIGS. 3A and 3B are schematic diagrams showing a top view (without lid) and a cross-sectional view (with lid) of a chip package 100 according to various non-limiting aspects;

FIG. 4A is a schematic diagram showing an enlarged view of a portion of the top view (without lid) of the chip package 100 corresponding to the inset indicated in FIG. 3A;

FIG. 4B is a table showing the dimensions of the lines and dots of the pattern of the second thermal interface material and dimensions of the dams according to various non-limiting aspects;

FIGS. 5A and 5B are schematic diagrams showing a top view (without lid) and a cross-sectional view (with lid) of a chip package 200 according to various non-limiting aspects;

FIG. 6 is a chart showing the results of a package warpage simulation comparing chip modules according to various embodiments to existing chip modules;

FIG. 7 is a chart showing the results of bond line thickness at the chip corners comparing chip modules according to various embodiments to existing chip modules;

FIG. 8 is a chart showing thermal simulations with different thermal conductivity of TIM1 material;

FIG. 9 is a chart showing the results of mechanical simulation for package corner stress comparing chip modules according to various embodiments to existing chip modules; and

FIG. 10 is a block diagram showing a process for assembling a chip package according to various non-limiting aspects.

### DETAILED DESCRIPTION

Aspects described below in the context of a method are analogously valid for the respective element, device, apparatus, or system, and vice versa. Furthermore, it will be understood that the aspects described below may be combined, for example, a part of one aspect may be combined with a part of another aspect, and a part of one aspect may be combined with a part of another aspect.

It should be understood that the singular terms “a”, “an”, and “the” include plural references unless context clearly indicates otherwise. Similarly, the word “or” is intended to include “and” unless the context clearly indicates otherwise.

It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Approximating language, as used herein throughout the specification and claims, may be applied to modify any quantitative representation that could permissibly vary without resulting in a change in the basic function to which it is related. Accordingly, a value modified by a term or terms, such as “about,” “substantially”, is not limited to the precise value specified but within tolerances that are acceptable for operation of the aspect for an application for which it is intended. In some instances, the approximating language may correspond to the precision of an instrument for measuring the value.

The term “exemplary” may be used herein to mean “serving as an example, instance, or illustration”. Any aspect or design described herein as “exemplary” is not necessarily to be construed as preferred or advantageous over other aspects or designs.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The term “first”, “second”, “third” detailed herein are used to distinguish one element from another similar element and may not necessarily denote order or relative importance, unless otherwise stated. For example, a first transaction data, a second transaction data may be used to distinguish two transactions based on two different foreign currency exchange.

As used herein, the term “connect/connected/connection” may refer to a wired or wireless communication link formed between electronic devices that enables data transmission.

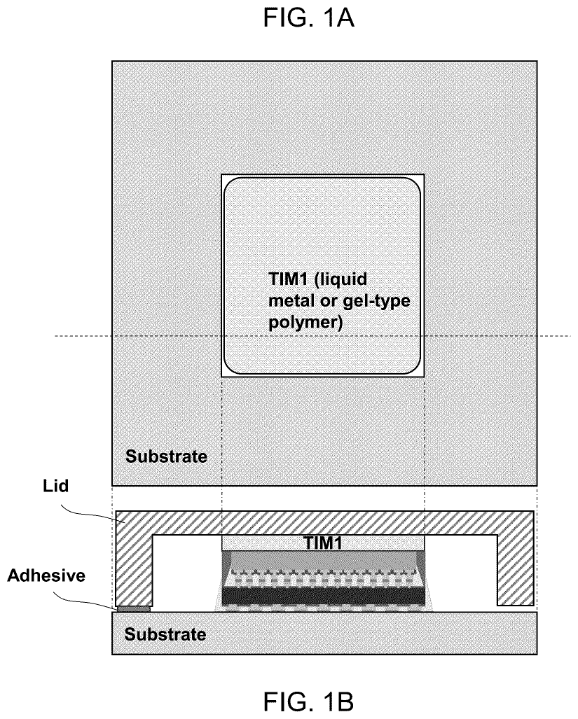

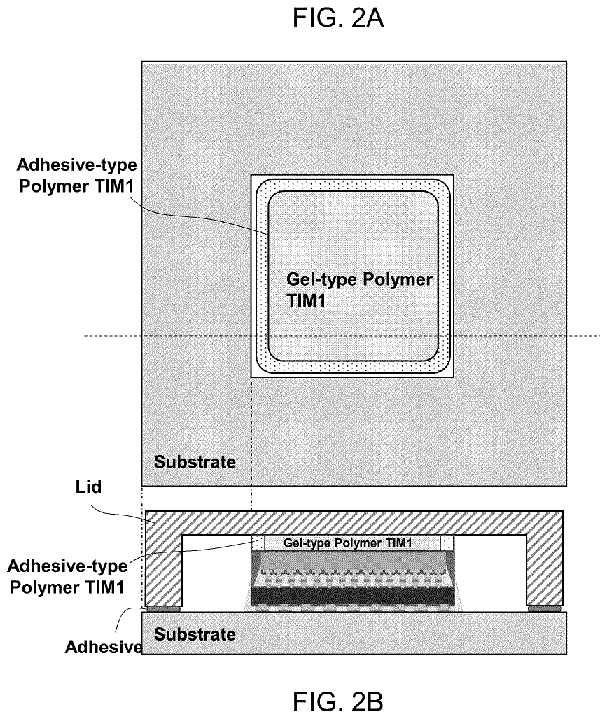

FIGS. 1A and 1B are schematic diagrams showing a top view (without lid) and a cross-sectional view (with lid) of a current chip package. FIGS. 2A and 2B are schematic diagrams showing a top view (without lid) and a cross-sectional view (with lid) of another current chip package.

Referring to FIGS. 1A and 1B, a current chip package may use a liquid or gel-type thermal interface material (TIM) between a lid and a die/chip module. However, liquid metal thermal interface material or gel-type polymer thermal interface material may eventually bleed or leak out, which may cause a short circuit (e.g., fall on components on the substrate) and/or degrade heat dissipation of the chip package (e.g., suspend from a side wall of the chip module instead of conducting heat from the die backside to the lid). Referring to FIGS. 2A and 2B, another current chip package may additionally use a second thermal interface material between the lid and the die/chip module to surround the liquid metal thermal interface material or gel-type polymer thermal interface material to prevent the liquid metal thermal interface material or gel-type polymer thermal interface material from leaking onto the substrate. As shown in FIGS. 2A and 2B, a liquid or gel type thermal interface material, e.g., TIM1 may be used in a central area of a die/chip module and an adhesive thermal interface material, e.g., TIM2 may be used to form a frame around the TIM1 to protect the TIM1 from bleeding out. In existing processes, the TIM2 is continually dispensed to form a frame of substantially uniform thickness around the TIM1. The advantage of this solution has good low bond line thickness (BLT) control, but the frame induces interfacial cracks in the mold or delamination of the chip package which will trigger failure of the chip package (e.g., moisture may have a weak spot to penetrate into the die and/or the circuits because the chip package is no longer fully protected by the mold. Even if the chip package does not fail, cracks and delamination may decrease thermal performance after repeated temperature cycles. That is, the frame increases the risk of damage to the integrity of the chip packaging and overtime will degrade heat dissipation efficiency of the thermal dissipation structures.

Various non-limiting aspects described herein seek to provide an advantageous and more reliable thermal management of advanced chip module packages.

A heat dissipation structure is provided based on a stress reducing pattern for hybrid thermal interface materials (e.g., a pattern for a combination of two thermal interface material) applied on a die/chip module and a stabilizing dam structure around the die/chip module (e.g., L-shape dam structures) in the advanced chip package.

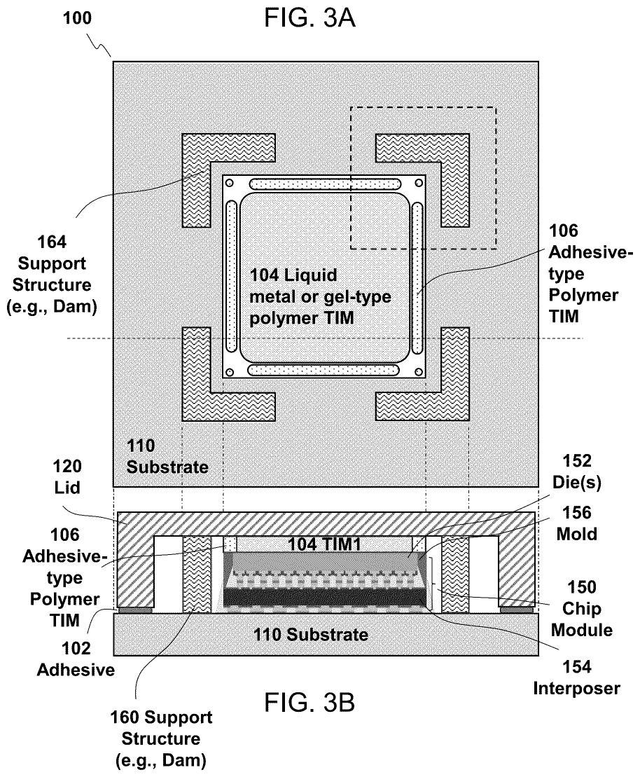

FIGS. 3A and 3B are schematic diagrams showing a top view (without lid) and a cross-sectional view (with lid) of a chip package 100 according to various non-limiting aspects.

Referring to FIG. 3B, a chip module 150 is mounted on a substrate 110. The chip module 150 may be mounted at a central portion of the substrate 110. The chip module 150 may include one or more dies 152 mounted on an interposer 154. The interposer 154 may be a silicon interposer or a redistribution layer (RDL) interposer. The interposer 154 is mounted to the substrate 110. The chip module 150 may include a mold 156 encapsulating the one or more chip dies 152. A lid 120 is mounted to cover the chip module 150. The lid 120 may include a top wall supported by side walls. The base of the side walls are coupled (e.g., attached) to the substrate 110. The top wall is thermally coupled to the die/chip module through a combination of thermal interface material disposed on the die/chip module. The combination of thermal interface material may be disposed on a surface of the die/chip module facing away from the substrate.

Referring to FIGS. 3A and 3B, a first thermal interface material is arranged on a top surface of the die 152 of the chip module 150 at a central portion of the die/chip module. The first thermal interface material is a liquid metal thermal interface material or gel-type polymer thermal interface material. For example, the first thermal interface material may be a silicone matrix with a liquid Gallium-based filler or other high thermal conductivity solid metal filler. A second thermal interface material is arranged on a top surface of the die 152 of the chip module 150 around the first thermal interface material. The second thermal interface material is a thermally conductive adhesive. The second thermal interface material may be an adhesive-type polymer thermal interface material. That is, the second thermal interface material may be an epoxy-based or silicone-based polymer adhesive including highly conductive metal fillers. The second thermal interface material is liquid/gel-like while dispensing, and which will turn into a solid/rigid form after curing process. For example, the second interface material may be an epoxy-based or silicone-based adhesive that is gel-like while dispensing, and which will turn into a solid/rigid form after a curing process.

Referring to FIG. 3A, a stress-reducing pattern of the second thermal interface material is provided. The stress-reducing pattern includes the second thermal interface material provided as four lines on the die/chip module with one line along each edge of the die/chip module and four dots on the die/chip module with one dot at each corner of the die/chip module. The second thermal interface material is an adhesive-type polymer thermal interface material. The purpose of this pattern is to reduce corner package stress and to protect the first thermal interface material (e.g., a liquid metal or gel-type polymer thermal interface material, i.e., TIM1) from bleeding out.

The second thermal interface material 106 is a liquid or gel-like prior to curing. The second thermal interface material 106 is dispensed onto the die/chip module 150 according to the stress-reducing pattern described above. When the lid is applied, the second thermal interface material may spread prior to curing. After curing, a thickness of the second thermal interface material at the corners of the die/chip module is less than a thickness of the second thermal interface material at the edges of the die/chip module. The thinner layer of the second thermal interface material at the corners of the die/chip module reduces the stress at the corners of the die/chip module. A thickness of the first thermal interface material may be the same as the thickness of the second thermal interface material at the edges of the die/chip module.

Additionally, a support structure 160 may be arranged around the die/chip module 150. The support structure 160 prevents leakage of the first thermal interface material 104, provides reinforcement to the substrate 110, provides support of the top wall of the lid 120 and determines the bond line thickness at the corners of the die/chip module 150. The support structure 160 is spaced apart from the die/chip module 150. The spacing between the support structure and the chip module may be greater than two times the height of the chip module and less than four times the height of the chip module.

In a non-limiting embodiment, the support structure 160 may include four dams 164 disposed around the die/chip module. Referring to FIG. 3A, each dam 164 may be L-shaped and arranged at a respective corner of the die/chip module 150. The inside corner of the L-shaped dam faces the corner of the chip module. Each dam 164 is spaced apart from the corner of the die/chip module. The spacing between each dam and the chip module may be greater than two times the chip module height and less than four times the chip module height. Referring to FIG. 3B, a height of each dam 164 extends from the substrate 110 to the lid 120 and a top of each dam is coupled (e.g., bonded) to the lid 120 and a bottom of each dam is coupled (e.g., bonded) to the substrate 110. The dams 164 is a structure to control the bond line thickness, control the package warpage, and prevent the first thermal interface material from bleeding out. The dam 164 may be formed from an epoxy-based material or polymer, but is not limited to adhesive or other bonding material. For example, the dam may be formed using an epoxy-based or silicone-based adhesive that is gel-like while dispensing, and which will turn into a solid/rigid form after curing process. Alternatively, each dam 164 may be a prefabricated piece and the dams 164 may be coupled (e.g., attached) to the substrate 110 and lid 120 using adhesives.

The discontinuous pattern of the second thermal interface material 106 forming the frame around the first thermal interface material provides flexibility for the frame to prevent the mold of chip module from cracking and the thermal interface materials delaminating from the surface of the chip module which results in reduction of thermal performance. The reduced amount of the second thermal interface material at the corners may reduce the control of thermal interface material thickness at the corners. The support structure 160 provides additional support to the lid to provide stability of thermal interface material thickness at the corners of the chip module since the discontinuous frame reduces constraint of the corner area.

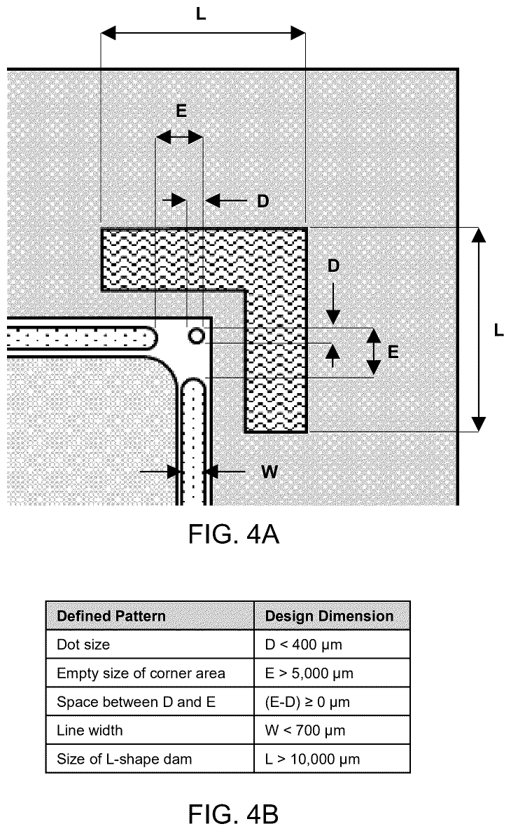

FIG. 4A is a schematic diagram showing an enlarged view of a portion of the top view (without lid) of the chip package 100 corresponding to the inset indicated in FIG. 3A according to various non-limiting aspects. FIG. 4B is a table showing the dimensions of the lines and dots of the pattern of the second thermal interface material and dimensions of the dams according to various non-limiting aspects. FIG. 4A is not drawn to scale. Detailed specification of the stress-reducing thermal interface material pattern with L-shape dam is shown in FIGS. 4A and 4B. Four dimensions including dot size, empty size of corner area, line width and length of the L-shape dam are provided. The second thermal interface material is provided according to the stress-reducing pattern. When the lid is applied, the lid contacts the first thermal interface material and the second thermal interface material and the first thermal interface material and second thermal interface material spread. That is, the application of the lid causes the second thermal interface material to spread and seal the first thermal interface material. The spreading also results in the thickness of the second thermal interface material at the corners of the die being less than or equal to the thickness of the second thermal interface material along the edges of the die. The thickness of the second thermal interface material at the corners should be less than the thickness of the second thermal interface material along the edges to reduce or minimize stress at the corners of the die. The thickness of the first thermal interface material on the die is determined by the dam structure and the second thermal interface material along the edges of the die.

Referring to FIGS. 4A and 4B, D corresponds to a size of a dot of the second thermal interface material dispensed at each corner of the die/chip module. The diameter of the dot should be less than 400 μm. W corresponds to a width of a line of the second thermal interface material dispensed along each side edge of the die/chip module. The width of the line should be less than 700 μm. E corresponds to an empty size of the corner area. That is, E indicates a distance between an end of each line from an edge of the chip module where the dot at each corner is disposed. E should be greater than 5,000 μm. A space between D and E corresponding to E-D should be greater than or equal 0 μm. The reduction of second thermal interface material at the corners achieves a lower thickness of second thermal interface material at the corners which reduces corner stress on the chip module. L corresponds to the length of each dam. The length of the dam should be greater than 10,000 μm. The width of the dam may depend on the warpage and other packaging factors. However, in general, the width of the dam should be greater than 1 mm. A spacing between a wall of the dam facing the chip module and a wall of the chip module facing the dam may be greater than two times the chip module height and less than four times the chip module height.

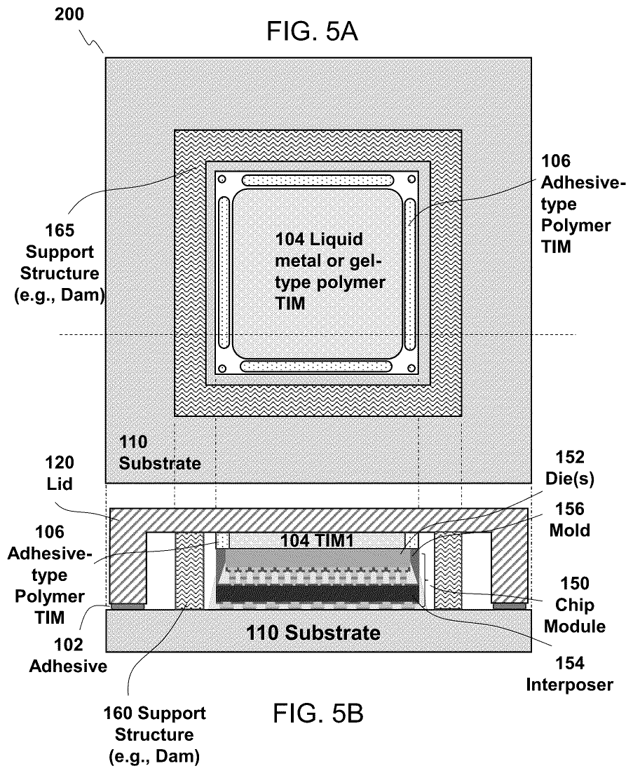

FIGS. 5A and 5B are schematic diagrams showing a top view (without lid) and a cross-sectional view (with lid) of a chip package 200 according to various non-limiting aspects. Referring to FIGS. 5A and 5B, the chip package 200 may be the same as chip package 100 except that support structure 160 includes a single dam 165 instead of the four corner dams 164. The dam 165 may be a rectangular ring or frame spaced apart from the die 152/chip module 150. The dam 165 is continuous and completely surrounds the perimeter of die/chip module. Referring to FIG. 5B, a height of the dam extends from the substrate 110 to the lid 120 and a top of the dam 165 is coupled (e.g., bonded) to the lid 120 and a bottom of the dam 165 is coupled (e.g., bonded) to the substrate 110. The dam 165 is a structure to control the bond line thickness, control the package warpage, and prevent the first thermal interface material from bleeding out. The dam 165 may be formed from an epoxy-based or silicon-based polymer, but is not limited to adhesive or other bonding material. The dam 165 may be coupled (e.g., attached) to the substrate 110 and lid 120 using adhesives.

Advantages include:

The stress-reducing hybrid thermal interface material pattern of a first thermal interface material at a center portion and a second thermal interface material surrounding the first thermal interface material, the second thermal interface material including four lines on the edges of the chip module and four dots on the corners of the chip module can reduce stress level effectively and provide better bond line thickness control for thermal performance.

Adding support structures (e.g., L-shape dams or framed dam) surrounding the chip module corner lowers reliability stress and lowers package warpage according to mechanical simulation.

The combination of these two features provides reliable bond line thickness control of the liquid metal thermal interface material or gel-like polymer thermal interface material to obtain sustainable thermal dissipation on advanced chip packages. The non-limiting embodiments help a packaging engineer or designer to design and manufacture a robust product.

Thermal-mechanical simulation for package warpage, first thermal interface material bond line thickness, and package reliability stress were conducted and validate the advantages.

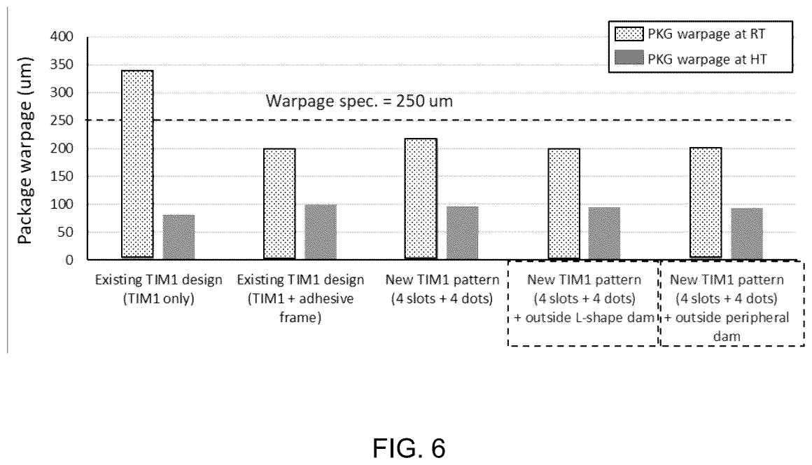

FIG. 6 is a chart showing the results of a package warpage simulation comparing chip modules according to various embodiments to existing chip modules. The simulation compared warpage at room temperature and at high temperature. The discontinuous corner dot/edge line pattern and dam structure show lower package warpage compared with chip modules according to existing designs as shown in FIG. 6. The warpage control of the present embodiments looks promising and can be lower than warpage spec. (250 μm).

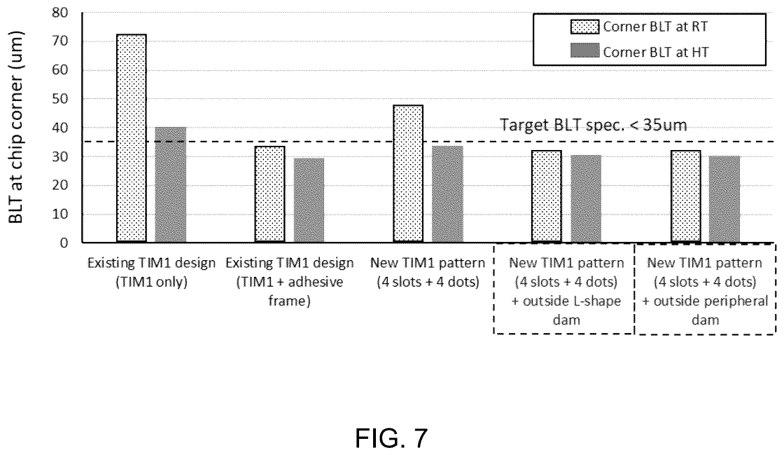

FIG. 7 is a chart showing the results of bond line thickness at the chip corners comparing chip modules according to various embodiments to existing chip modules. The simulation compared bond line thickness at the chip corner at room temperature and at high temperature. The lower bond line thickness of TIM1 has better heat dissipation from the die to heat spreader. In the present embodiments, the corner bond line thickness can be lower than 35 μm by the simulation.

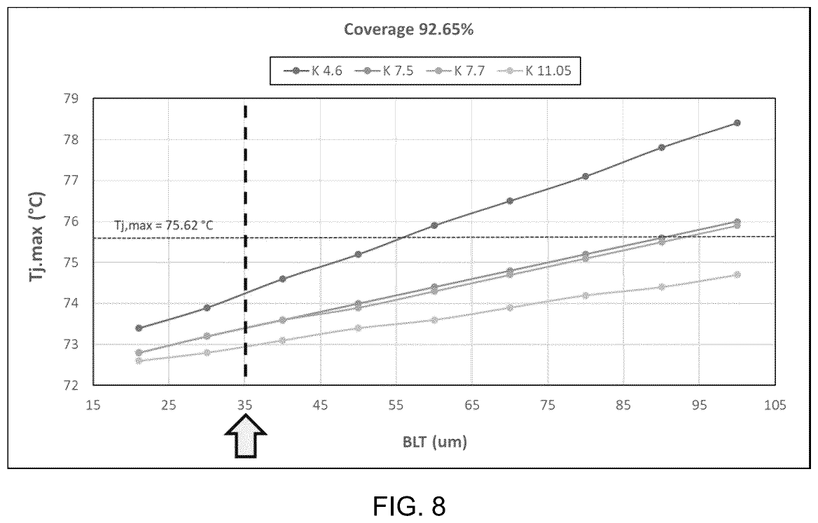

FIG. 8 is a chart showing thermal simulations with different thermal conductivity of TIM1 material. According to the thermal simulation with difference thermal conductivity of TIM1 material as shown in FIG. 8. The junction temperature (Tj) of the present embodiments become much lower than reference junction temperature.

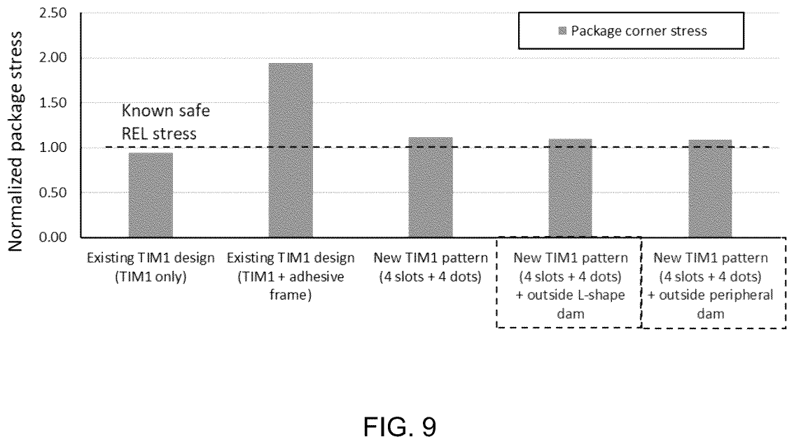

FIG. 9 is a chart showing the results of mechanical simulation for package corner stress comparing chip modules according to various embodiments to existing chip modules. By packaging mechanical stress simulation, the existing chip module design with adhesive frame shows much higher package corner stress. The present embodiments reduce the package corner stress to the stress level which is near the known safe stress level of reliability data.

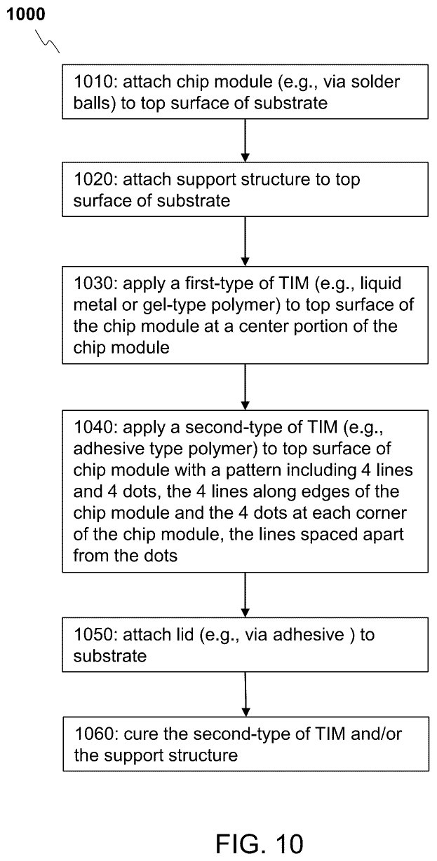

FIG. 10 is a block diagram showing a process for assembling a chip package according to various non-limiting aspects.
At 1010: couple (e.g., attach via solder balls) a chip module to a top surface of the substrate.
At 1020: couple a support structure (e.g., attach a dam) to the top surface of the substrate. For example, the support structure may be formed using an epoxy-based or silicone-based adhesive that is gel-like while dispensing, and which will turn into a solid/rigid form after a curing process. That is, an adhesive-type polymer may be applied to a top surface of the substrate to form the support structure which becomes coupled (e.g., attached) to the substrate and lid after a curing process. Alternatively, the support structure may a prefabricated piece and the support structure may be coupled (e.g., attached) to the substrate and lid using adhesives.
At 1030: apply a first thermal interface material (e.g., TIM1 or first type of thermal interface material such as a liquid metal or gel-type polymer) to the surface of the chip module at a center portion of the chip module.
At 1040: apply a second thermal interface material (e.g., TIM2 or second type of thermal interface material such as an adhesive-type polymer) to a top surface of the chip module with a pattern including 4 lines and 4 dots, the 4 lines along edges of the chip module and the 4 dots at each corner of the chip module, the lines spaced apart from the dots. For example, the second thermal interface material may be an epoxy-based or silicone-based adhesive that is gel-like while dispensing, and which will turn into a solid/rigid form after a curing process.
At 1050: couple (e.g., attach via adhesive) the lid to the substrate. For example, the adhesive may be a silicone-based or epoxy-based adhesive. When the lid is applied (e.g., provided or added), the lid contacts the first thermal interface material and the second thermal interface material and the first thermal interface material and second thermal interface material spreads. The second thermal interface material spreads (e.g., to reduce the gap between the dot and the end of the line) and seal the first thermal interface material. The lid also contacts the support structure. When the support structure is formed using an epoxy-based or silicone-based adhesive, the lid becomes coupled (e.g., attached) to the support structure.
At 1060: cure the second thermal interface material and/or the support structure. For example, the curing process may include a snap cure and a hard cure of the adhesive material. For example, the second thermal interface material and support structure comprising adhesive material may undergo an initial snap cure then a hard cure with an oven.

Example 1 may be a device including: a substrate; a chip module coupled (e.g., bonded) to a top surface of the substrate; a first thermal material disposed on a top surface of the chip module; a second thermal material disposed on the top surface of the chip module forming a frame surrounding the first thermal material; a lid structure disposed over the chip module and coupled (e.g., attached) to the substrate along a perimeter of the lid structure, wherein a central portion of the lid structure is in thermal contact with the first thermal material and the second thermal material; and a support structure disposed around the chip module and covered by the lid structure, the support structure extending vertically from the substrate to the lid structure.

Example 2 may be the device of Example 1 or another example herein, wherein the first thermal material is a liquid metal or a gel-type polymer and the second thermal material is an epoxy-based or silicone-based polymer adhesive including highly conductive metal fillers.

Example 3 may be the device of any one of Examples 1-2 or another example herein, wherein the support structure is coupled (e.g., attached) to the substrate and coupled (e.g., attached) to the lid structure.

Example 4 may be the device of any one of Examples 1-3 or another example herein, wherein the support structure is an epoxy-based material or polymer material.

Example 5 may be the device of any one of Examples 1-4 or another example herein, wherein the support structure is spaced apart from the chip module.

Example 6 may be the device Example 5 or another example herein, wherein the spacing between the support structure and the chip module is greater than two times a chip module height and less than four times the chip module height.

Example 7 may be the device of any one of Examples 1-6 or another example herein, wherein the support structure comprises a continuous wall around the chip module.

Example 8 may be the device of any one of Examples 1-6 or another example herein, wherein the support structure comprises four L-shaped walls arranged by each corner of the chip module.

Example 9 may be the device of any one of Examples 1-8 or another example herein, wherein the second thermal material is disposed in a stress-reducing pattern along a perimeter of the chip module including a dot of the second thermal material at each corner of the top surface of the chip module and a line of the second thermal material along each side edge of the top surface of the chip module, wherein the respective dots and lines are spaced apart from each other.

Example 10 may be the device of any one of Examples 1-9 or another example herein, wherein the second thermal material at each corner of the top surface of the chip module has a first thickness and the second thermal material along each side edge of the top surface of the chip module has a second thickness, and wherein the first thickness is less than or equal to the second thickness.

Example 11 may be the device of Example 10 or another example herein, where a thickness of the first thermal material is the same as the second thickness.

Example 12 may be the device of any one of Examples 10-11 or another example herein, wherein the first thickness is less than the second thickness.

Example 13 may be a device including: a substrate; a chip module coupled (e.g., bonded) to a top surface of the substrate; a first thermal material disposed on a top surface of the chip module; a second thermal material disposed on the top surface of the chip module forming a discontinuous frame surrounding the first thermal material, a lid structure disposed over the chip module and coupled (e.g., bonded) to the substrate along a perimeter of the lid structure, wherein a central portion of the lid structure is in thermal contact with the first thermal material and the second thermal material; and a support structure arranged around the chip module and covered by the lid structure, the support structure extending vertically from the substrate to the lid structure.

Example 14 may be the device of Example 13 or another example herein, wherein the discontinuous frame comprises: a dot of the second thermal material at each corner of the top surface of the chip module; and a line of the second thermal material along each side edge of the top surface of the chip module.

Example 15 may be the device of Example 14 or another example herein, wherein the respective dots and lines are spaced apart from each other.

Example 16 may be the device of any one of Examples 13-15 or another example herein, wherein the support structure is coupled (e.g., attached) to the substrate and coupled (e.g., attached) to the lid structure.

Example 17 may be the device of any one of Examples 13-16 or another example herein, wherein the support structure is spaced apart from the chip module.

Example 18 may be the device of any one of Examples 13-17 or another example herein, wherein the support structure comprises a continuous wall around the chip module.

Example 19 may be the device of any one of Examples 13-17 or another example herein, wherein the support structure comprises four L-shaped walls arranged by each corner the chip module.

Example 20 may be a method including: coupling (e.g., attaching) a chip module to a top surface of the substrate; providing a support structure to the top surface of the substrate, the support structure disposed around the chip module; providing a first thermal material at a central portion of a top surface of the chip module, the top surface facing away from the substrate; providing a second thermal material on the top surface of the chip module; providing a lid structure to cover the chip module and coupling (e.g., attaching) the lid structure to the substrate along a perimeter of the lid structure, wherein a central portion of the lid structure is in thermal contact with the first thermal material and the second thermal material, wherein the first thermal material is surrounded by the second thermal material, wherein the support structure is coupled (e.g., attached) to the substrate and is covered by the lid structure, the support structure extending vertically from the substrate to the lid structure.

Example 21 may be the method of Example 20 or another example herein, wherein the second thermal material forms a discontinuous frame along a perimeter of the chip module, wherein the discontinuous frame comprises: a dot of the second thermal material at each corner of the top surface of the chip module; and a line of the second thermal material along each side edge of the top surface of the chip module.

Example 22 may be the method of Example 21 or another example herein, wherein the respective dots and lines are spaced apart from each other.

Example 23 may be the method of any one of Examples 21-22 or another example herein, wherein when the lid structure is provided (e.g., added), the second thermal interface material spreads to reduce the gaps between the respective dots and lines and seal the first thermal material.

Example 24 may be the method of any one of Examples 21-23 or another example herein, wherein the second thermal material at each corner of the top surface of the chip module has a first thickness; and the second thermal material along each side edge of the top surface of the chip module has a second thickness, wherein the first thickness is less than or equal to the second thickness.

Example 25 may be the method of any one of Examples 20-24 or another example herein, further comprising coupling (e.g., attaching) the support structure to the substrate and to the lid structure.

Example 26 may be the method of any one of Examples 20-25 or another example herein, wherein the support structure is an epoxy-based material or polymer material.

Example 27 may be the method of any one of Examples 20-26 or another example herein, wherein the support structure is spaced apart from the chip module.

Example 28 may be the method of Examples 27 or another example herein, wherein the spacing between the support structure and the chip module is greater than two times a chip module height and less than four times the chip module height.

Example 29 may be the method of any one of Examples 20-28 or another example herein, wherein the support structure comprises a continuous wall around the chip module.

Example 30 may be the method of any one of Examples 20-28 or another example herein, wherein the support structure comprises four L-shaped walls arranged by each corner of the chip module.

Example 31 may be the method of any one of Examples 20-30 or another example herein, wherein the first thermal material is a liquid metal or a gel-type polymer and the second thermal material is an epoxy-based or silicone-based polymer adhesive including highly conductive metal fillers.

Example 32 may be the method of any one of Examples 20-31 or another example herein, further comprising allowing the second thermal material to cure.

Example 33 may be the method of any one of Examples 20-32 or another example herein, wherein the support structure is a prefabricated piece.

Example 34 may be the method of any one of Examples 20-32 or another example herein, wherein providing the support structure comprises providing adhesive material as four L-shaped walls arranged by each corner of the chip module.

Example 35 may be the method of any one of Examples 20-32 or another example herein, wherein providing the support structure comprises providing adhesive material as continuous wall around the chip module.

Example 36 may be the method of any one of Examples 34-35 or another example herein, further comprising allowing the adhesive material of the support structure to cure.

While this specification contains many details, these should not be understood as limitations on the scope of what may be claimed, but rather as descriptions of features specific to particular examples. Certain features that are described in this specification or shown in the drawings in the context of separate aspects can also be combined. Conversely, various features that are described or shown in the context of a single aspect can also be implemented in multiple aspects separately or in any suitable sub-combination.

Similarly, while steps/operations of the methods as described above are depicted in a particular order (e.g. as shown in the drawings), this should not be understood as requiring that such operations/steps be performed in the particular order shown or in sequential order, or that all illustrated operations be performed, to achieve desirable results. In certain circumstances, multitasking and parallel processing may be advantageous. For example, some operations/steps may occur in different orders and/or concurrently with other operations/steps apart from those illustrated and/or described herein. In addition, not all illustrated operations/steps may be required to implement one or more aspects or aspects described herein. Also, one or more of the steps depicted herein may be carried out in one or more separate acts and/or phases.

Moreover, the separation/integration of various system components in the aspects described above should not be understood as requiring such separation/integration in all aspects, and it should be understood that the described program components and systems can generally be integrated together in a single product or separated into multiple products.

A number of aspects have been described. Nevertheless, it will be understood that various modifications can be made. Accordingly, other aspects are within the scope of the following claims.

What is claimed:

1. A device comprising:
a substrate;
a chip module coupled to a top surface of the substrate;
a first thermal material disposed on a top surface of the chip module;
a second thermal material disposed on the top surface of the chip module
forming a frame surrounding the first thermal material;
a lid structure disposed over the chip module and coupled to the substrate along a perimeter of the lid structure, wherein a central portion of the lid structure is in thermal contact with the first thermal material and the second thermal material; and
a support structure disposed around the chip module and covered by the lid structure, the support structure extending vertically from the substrate to the lid structure.

2. The device of claim 1, wherein the first thermal material comprises a liquid metal or a gel-type polymer and the second thermal material comprises an epoxy-based or silicone-based polymer adhesive including highly conductive metal fillers.

3. The device of claim 1, wherein the support structure comprises an epoxy-based material or polymer material.

4. The device of claim 1, wherein the support structure is spaced apart from the chip module.

5. The device of claim 4, wherein the spacing between the support structure and the chip module is greater than two times a chip module height and less than four times the chip module height.

6. The device of claim 1, wherein the support structure comprises a continuous wall around the chip module.

7. The device of claim 1, wherein the support structure comprises four L-shaped walls arranged by each corner of the chip module.

8. The device of claim 1, wherein the second thermal material is disposed in a stress-reducing pattern along a perimeter of the chip module including a dot of the second thermal material at each corner of the top surface of the chip module and a line of the second thermal material along each side edge of the top surface of the chip module, wherein the respective dots and lines are spaced apart from each other.

9. The device of claim 1, wherein the second thermal material at each corner of the top surface of the chip module has a first thickness and the second thermal material along each side edge of the top surface of the chip module has a second thickness, and
wherein the first thickness is less than or equal to the second thickness.

10. The device of claim 9, where a thickness of the first thermal material is the same as the second thickness.

11. The device of claim 10, wherein the first thickness is less than the second thickness.

12. A method, comprising:
coupling a chip module to a top surface of the substrate;
providing a support structure to the top surface of the substrate, the support structure disposed around the chip module;
providing a first thermal material at a central portion of a top surface of the chip module, the top surface facing away from the substrate;
providing a second thermal material on the top surface of the chip module;
and
providing a lid structure to cover the chip module and coupling the lid structure to the substrate along a perimeter of the lid structure, wherein a central portion of the lid structure is in thermal contact with the first thermal material and the second thermal material,
wherein the first thermal material is surrounded by the second thermal material;
wherein the support structure is coupled to the substrate and covered by the lid structure, the support structure extending vertically from the substrate to the lid structure.

13. The method of claim 12, wherein providing the second thermal material comprises providing the second thermal material as a discontinuous frame along a perimeter of the chip module, wherein the discontinuous frame comprises:
a dot of the second thermal material at each corner of the top surface of the chip module; and
a line of the second thermal material along each side edge of the top surface of the chip module, and
wherein the respective dots and lines are spaced apart from each other.

14. The method of claim 13, wherein when the lid structure is provided, the second thermal interface material spreads to reduce the gaps between the respective dots and lines and seal the first thermal material.

15. The method of claim 14, wherein the second thermal material at each corner of the top surface of the chip module has a first thickness; and the second thermal material along each side edge of the top surface of the chip module has a second thickness, wherein the first thickness is less than or equal to the second thickness.

16. The method of claim 12, wherein the support structure is an epoxy-based material or polymer material.

17. The method of claim 12, wherein the support structure is spaced apart from the chip module.

18. The method of claim 17, wherein the spacing between the support structure and the chip module is greater than two times a chip module height and less than four times the chip module height.

19. The method of claim 12, wherein the support structure comprises a continuous wall around the chip module.

20. The method of claim 12, wherein the support structure comprises four L-shaped walls arranged by each corner of the chip module.
